(19) United States
(12) Patent Application Publication
(10) Pub. No.: US 2005/0017878 A1
(43) Pub. Date: Jan. 27, 2005

(54) Serial weightless data to thermometer coded data converter

(76) Inventor: James Robert Armstrong, Lancashire (GB)

Correspondence Address: NIXON & VANDERHYE, PC, 1100 N GLEBE ROAD, 8TH FLOOR, ARLINGTON, VA, 22201-4714, US

(21) Appl. No.: 10/475,701

(22) PCT Filed: Feb. 21, 2003
(86) PCT No.: PCT/GB03/00732

(30) Foreign Application Priority Data
Feb. 25, 2002 (GB) 0204410.5

(51) Int. Cl. H03M 7/00; H03M 9/00

(52) U.S. Cl. 341/50; 341/100

(57) ABSTRACT

Apparatus and methods are described for converting a serial input stream of weightless binary digits into a thermometer code in which there is provided a sequence of bit stores 12₁, to 12₈ each capable of storing a binary digit. An input device (14) inputs set bits (1's) at one end of said sequence and unset bits (0's) at the other of said sequence, in each case with the existing bits being moved along in the corresponding direction to accommodate the new set bit, with the bit at the other end of the sequence being “lost”.

### BACKGROUND TO THE INVENTION

This invention relates to apparatus and methods for the generation of weightless thermocode, and to further apparatus such as Hamming value comparators and digital filter apparatus which utilise weightless thermocode generation.

### DEFINITIONS

Weightless binary: This means that each active bit has unit weight—just “1” as opposed to “natural” weighted binary which has positional weightings of 1, 2, 4, 8 . . . .

Weightless binary tuple: This defines a collection of weightless bits in which the order is irrelevant. For example, [0 0 1 1 ], [ 1 1 0 0] and [1 0 1 0] each have the same significance.

Thermometer code (alternatively referred to as thermocode): This is a form of weightless binary in which the 1's and 0's within the tuple are grouped together. For example, [1 0 1 0 1] in thermocode is [1 1 1 0 0] or, alternatively, [0 0 1 1 1].

Hamming value (Hv): This is the number of 1's within a tuple. For example [1 0 1 0 1 1] has a Hamming value of 4.

There are many applications where it is required to convert a fast serial stream of weightless data into thermocode in order to carry out further processing. Streams of weightless data are commonly found in weightless neural network systems, for example in the sum-and-threshold areas of the network. The sum-and-threshold section of the weightless neural network needs to be robust and fast.

This technique is particularly useful in neural networks which generate the data in a stream such as “ADAM” (J. Austin, “ADAM: A Distributed Associative Memory for Scene Analysis” in Proc. First Int. Conf. on Neural Networks IEEE. EDS. M. Caudhill and C. Boulter. volume 4, 1987) and so-called “neuroram” neural networks and neural memory of the type disclosed in International Published Patent Application WO 99/33019. Other applications are for use in compression and decompression systems such as are found in image and communications systems. The methods and apparatus described herein are also suited to performing high speed aggregate encoding in which a stream of weightless data is supplied to a two-or higher-dimensional array and the set bits are caused to aggregate towards or around a particular bit position.

Accordingly the apparatus and methods may be used in the following application fields: sum-and-thresholding in neural networks; signal converters; error correction systems; digital filters; compression codes, and implementing high speed aggregate encoding, and many others.

U.S. Pat. No. 6,262,676 discloses a weightless to thermometer code converter which operates on discrete tuples and which processes in parallel the bits making up the tuple in a succession of stages. There is no suggestion of a system which operates on a continuous stream of binary digits to keep a running thermometer code conversion.

Accordingly, in one aspect, this invention provides apparatus for converting a serial input stream of weightless binary digits into a thermometer code, which comprises:

at least one sequence of bit stores each capable of storing a binary digit, said sequence having a first end and a second end,

input means for receiving said input stream of weightless binary digits and for operating bitwise in use to control the distribution of bits in said bit stores, such that an operation corresponding to or equivalent to the following is performed:

(i) in response to a set bit (1) a bit is set in the bit store at a given end of said sequence and any other set bits in said bit stores are moved incrementally by one bit store towards the other end of the sequence, and

(ii) in response to an unset bit (0) a bit is unset in the bit store at the other end of said sequence and any other unset bits in said bit stores are moved incrementally towards said given end,

whereby the contents of said bit stores represent a thermometer code tuple corresponding to said serial input stream.

The operation performed by the input means may be implemented in many different ways. For convenience we refer to set bits being moved or shifted incrementally along the sequence; it should be appreciated that this terminology is used for convenience and, whilst in some instances the “same” bit may be shifted between adjacent bit stores, in many instances whether or not a bit is set will depend on a number of logic operations carried out on the bits in the other bit stores, rather than receiving a bit from an adjacent bit store.

In general, the sequence of bit stores will have a “1” end and a “0” end. If a “1” is input at the “1” end the 1's are shifted one bit towards the “0” end, and then the final 0 at the “0” end of the array will “overflow”. Likewise if a “0” is input at the “0” end the 0's are shifted one bit towards the “1” end and the final “1” overflows.

Each of said bit stores preferably comprises a flip flop, for example a D-type flip flop.

The input means preferably comprises a network of logic modules associated with respective ones of said bit stores, with each logic module receiving the current bit in said input stream, and the bits stored in at least one of the adjacent bit stores in said sequence.

Conveniently the logic modules comprise first and last logic modules of different forms associated with the bit stores at the respective ends of the sequence, with the intermediate logic modules being of common form.

In many instances the thermocoder will be used as part of a larger device and the layout of the bit stores can be important in such devices. For example, the apparatus may be configured to operate as a planar aggregate coder, wherein the bit stores are arranged generally in a two-dimensional regular array, with a bit store at one corner of the array defining the first end of said sequence and a bit store in the opposite corner of the array defining the second end of said sequence, with the sequence progressing in serpentine fashion, whereby in use the set bits are grouped in a generally triangular group of said bit stores with the apex of said group being defined by a given one of said end bit stores.

Alternatively, the apparatus may be configured to act as a spiral aggregate coder wherein the bit stores are arranged generally in a spiral, with an innermost one of said bit stores defining the first end of said sequence and an outermost one of said bit stores defining the other end of said sequence, and the sequence of bit stores progressing generally spirally between the innermost and the outermost. With this arrangement, the apparatus may be configured to cause the 1's from the input stream generally to congregate at the centre of the spiral, or for 0's to congregate generally at the centre of the spiral.

In yet a further arrangement, the bit stores may be arranged in a three- or higher-dimensional array with the sequence extending through the array such that, in operation, the set bits aggregate about or towards a preset bit store or in said array.

In one particular arrangement there is a two- or higher-dimensional array of bit stores in which a linear selection of bit stores (for example a row) defines said sequence, with the apparatus further including means for shifting the bits from said linear selection (e.g. row) to another linear selection of bit stores. As a further development, the bits from said linear selection (e.g. a row) may be incremented in turn to ripple through a succession of linear selections (e.g. rows) of bit stores.

In one configuration, the array of bit stores is two-dimensional with a row (or column) of bit stores comprising said linear selection, and clock means to clock the values in said bit stores through the remaining rows (or columns) of the array. In this instance the values in the bit stores may be envisaged as forming a matrix and there may be means for operating on the values in the bit stores to obtain a filtered output. For example, the means for operating may perform a sum-and-threshold operation for each of the columns of the matrix.

In another aspect, there is provided a Hamming value comparator device for receiving a first stream of weightless binary values and a second stream of weightless binary values and for determining a Hamming value relationship between said first and second values, the device comprising a first and second thermometer coder each comprising at least one sequence of bit stores and each comprising input means for receiving the associated first or second stream of weightless binary values and for operating bitwise in use to control the distribution of bits in the associated thermometer coder such that an operation corresponding to or equivalent to the following is performed:

(i) in response to a set bit (1) a bit is set in the bit store at a given end of said sequence and any other set bits in said bit stores are moved incrementally by one bit store towards the other end of the sequence and

(ii) in response to an unset bit (0) a bit is unset in the bit store at the other end of said sequence and any other unset bits in said bit stores are moved incrementally towards said given end,

whereby the contents of said bit stores represent a thermometer code tuple corresponding to said serial input stream, and comparison means for comparing the two thermometer codes to determine a Hamming value relationship.

In another aspect, this invention provides a method of converting a serial stream of weightless data into thermometer code, which method comprises providing a sequence of bit stores and performing in use an operation corresponding to or equal to one in which:

(i) in response to a set bit (1), a set bit is introduced into the bit store at one end of the sequence and the existing bits in the store are each moved one bit store towards the other of the sequence, and

(ii) in response to an unset bit (0), an unset bit is introduced into the bit store at the other end of the sequence and the existing bits are moved one bit store towards said one end of the sequence.

Whilst the invention has been described above, it extends to any inventive combination of the features set out above or in the following description.

The invention may be performed in various ways, and certain embodiments will now be described by way of example only, reference being made to the accompanying drawings, in which:

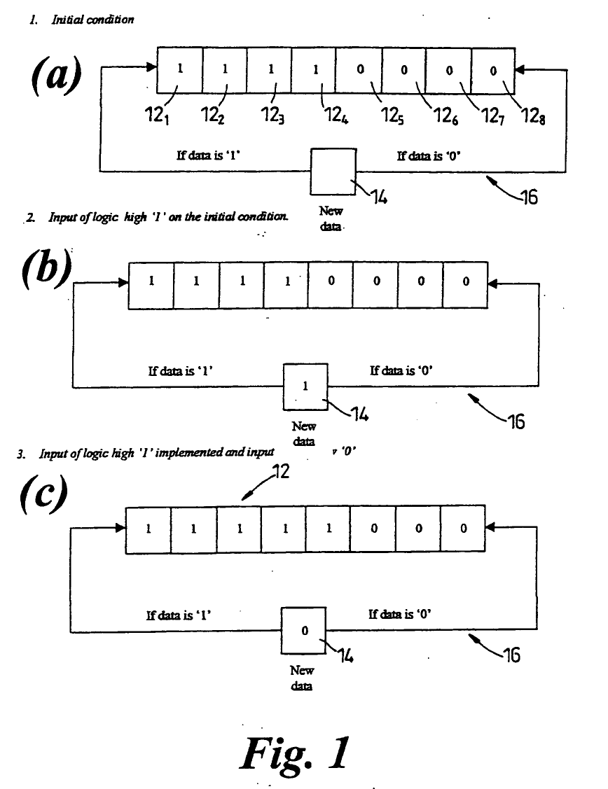

FIG. 1 is a schematic diagram illustrating the basis of operation of a thermocode generator operating in accordance with this invention;

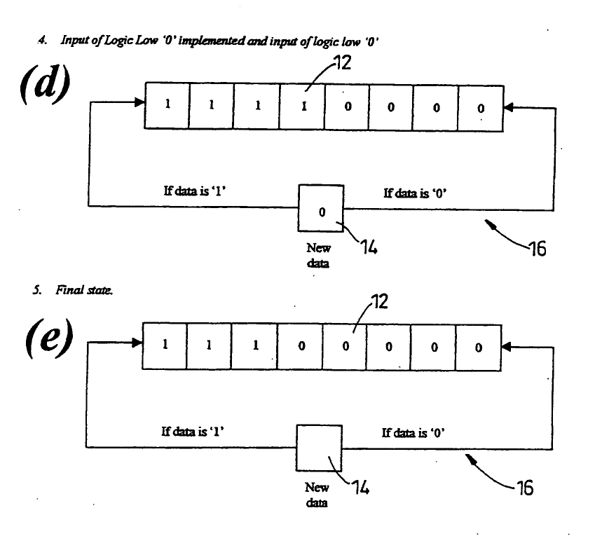

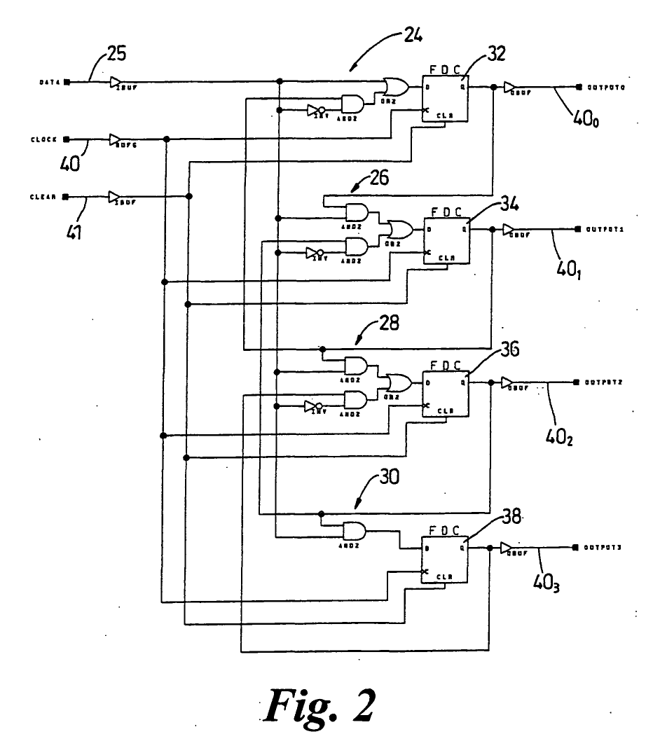

FIG. 2 is a circuit diagram showing an example of an implementation of a thermocode generator of this invention;

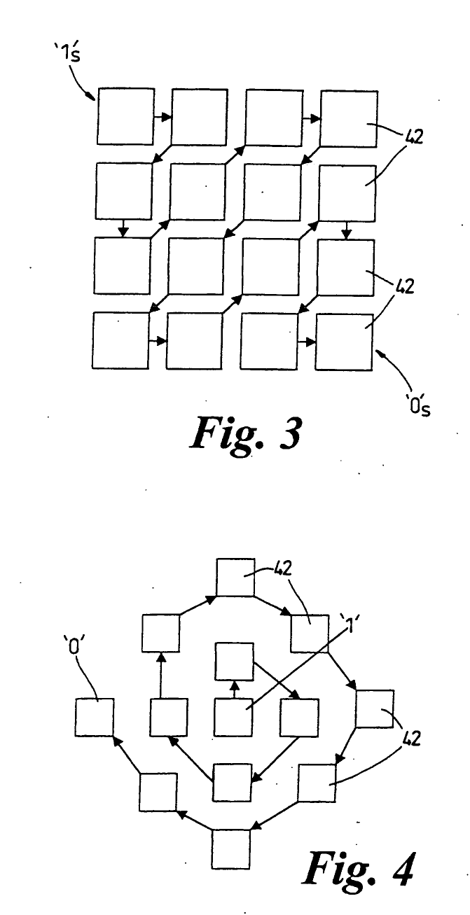

FIG. 3 is a diagram of a planar aggregate coder in accordance with this invention;

FIG. 4 is a diagram of a spiral coder in accordance with this invention;

FIG. 5 is an example of a sum-and-threshold device using two weightless thermocode generators in accordance with this invention;

FIG. 6 is a diagram of a Hamming value comparator for use in the sum-and-threshold device of FIG. 5, and

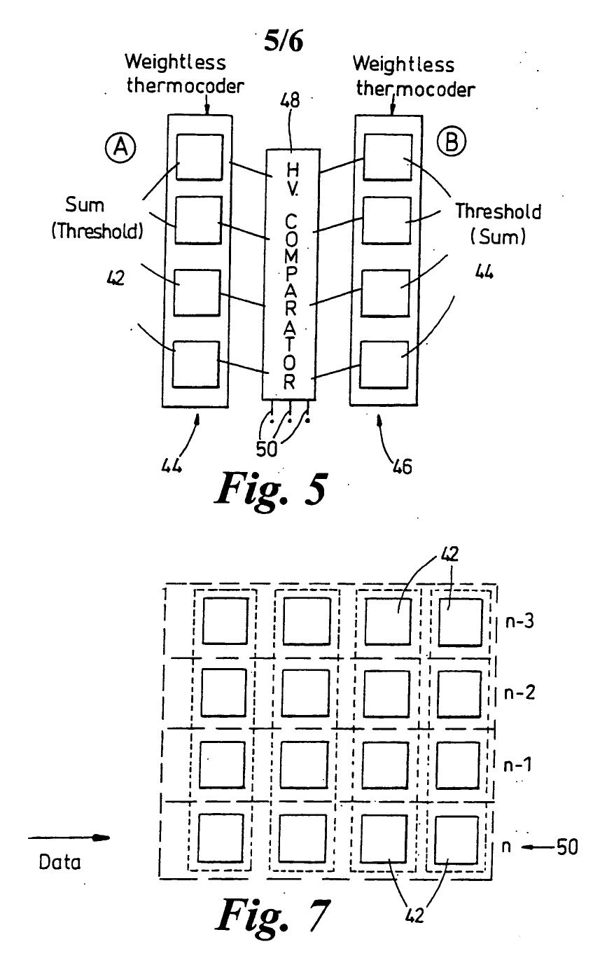

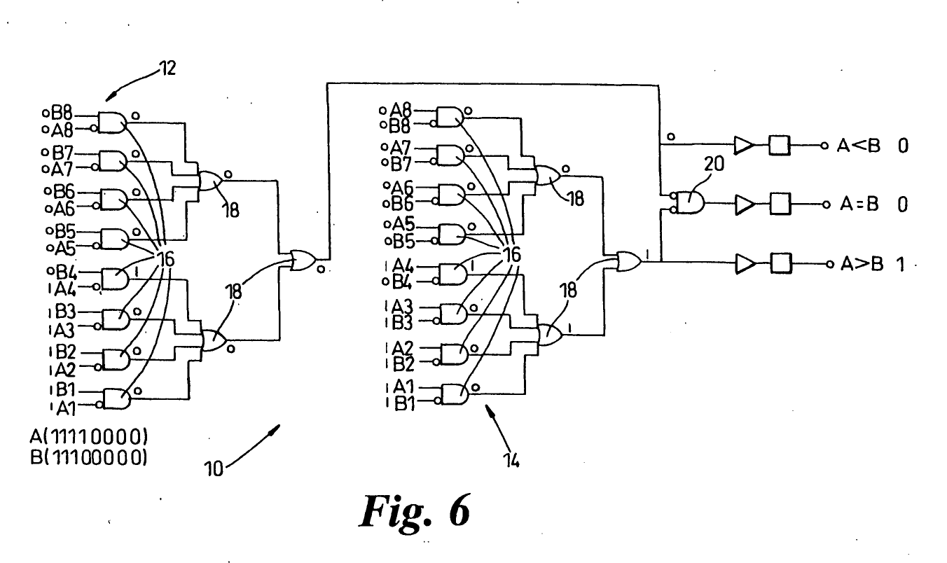

FIG. 7 is an example of a two-dimensional device having a single row operating as a thermocode generator and a series of stacked rows for receiving in sequence the data from the thermocode generator row.

The techniques disclosed herein are based around a chain of flip flops that shift data left or right on the next clock pulse depending on the value of the incoming data. It should be noted that this technique could be implemented for example in a processor but that this would be considered too slow and not as robust for some applications. This particular implementation is not however excluded.

Referring to FIG. 1, the apparatus 10 comprises a series of bit stores 12 (in this example 8-bit stores 12₁-12₈, together with a circuit 16 which receives new data bitwise in a new bit store 14. The operation of the circuit may be envisaged as implementing a shift left operation or a shift right operation depending on whether the incoming data is “1” or “0”. As the incoming data is introduced into the chain, a bit of data is lost at the other end of the chain.

FIG. 1a shows the initial condition with the four leftmost bit stores having 1's and the four rightmost bit stores having 0's.

FIG. 1b shows the arrangement on arrival of the first bit (here a logic high “1” at the input circuit). It is held in the new bit store 14 until the next clock cycle. At the next clock cycle (FIG. 1c), the “1” in the new bit store has passed into the leftmost end of the array, shifting the existing 1's one to the right, and the next input digit (0) is held in the new bit store 14. At the next clock cycle, the 0 passes to the right hand end of the array causing the 1's to increment one position to the left, with the leftmost 1 being “lost”, and the next serial digit (0) is held in the new bit store (FIG. 1d). At the next clock cycle, the 0 held in the new bit store is passed to the rightmost end of the array and again the 1's increment one to the left and the last 1 is lost.

The technique continues to operate in this fashion. It should be noted that due to the set bits and unset bits overflowing, that the instantaneous 8-bit tuple held on the bit stores may not be an exact thermocode conversion of the last eight digits in the stream of data but it will provide a good running approximation to the “exact” thermocode and, for the purposes of this specification, such approximations to the thermocode are also embraced by the term thermocode and similar.

Whilst in FIG. 1 the thermocode generator is explained by reference of an array of bit stores and a left feed or right feed according to whether the data is “1” or “0” there are many different implementations possible. For example, with reference to FIG. 2, there is shown an arrangement for converting a serial stream of input data into a rolling 4-bit thermometer code. In this embodiment the data is input on an input line 25 which supplies the input bit to each of a series of logic modules 24, 26, 28, 30. Each module applies Boolean logic and the output of each module supplies a respective D-type flip flop 32, 34, 36 and 38. The flip flops 32 to 38 each have clock inputs receiving a clock signal on line 40. Likewise each flip flop may be cleared by a “clear” signal input on line 41. Each flip flop has an output 40₀ 40₁ 40₂ and 40₃. respectively.

The first logic module comprises an OR gate and an AND gate and an inverter connected as shown. The two intermediate logic modules are the same form and are made up of two AND gates, an OR gate and an inverter connected as shown. The last logic module comprises a single AND gate as shown.

The logic modules perform the following Boolean operations:-

output₀=[input] OR [output₁ AND \overline{input}]

output₁=[output₀ AND input] OR [output₂ AND \overline{input}]

output₂=[output₁ AND input] OR [output₃ AND \overline{input}]

output₃=input AND output₂.

In operation, a (1) on the input line sets output₀ to 1 and shifts any set bits downward by 1. Likewise a 0 will produce a 0 at output₃ and shift any 1's in the remaining flip flops upwards.

Referring now to FIGS. 3 and 4, the flip flops may be arranged in particular two- or higher-dimensional arrays to provide a required bit distribution. This may be of particular interest when the thermocoder is being used as a component in the larger processor which is made up of two or more actual or notional layers with the data bits from, say, the two-dimensional layer of flip flops passing to an adjacent layer in which another operation is carried out.

Thus in FIG. 3, the flip flops 42 are arranged in a 4×4 rectangular array and the input circuitry (not shown) is configured such that the sequence of the flip flops (that is the order in which bits propagate through the array) starts, in this example, in the top left hand corner and then passes back and forth in a serpentine diagonal fashion across the flip flops of the array to terminate at the bottom right hand of the flip flop. Obviously, this sequence could be reversed or it could start at either of the other corners and progress in similar fashion. This array performs as a planar aggregate coder, with e.g. the 1's aggregating towards the top left hand corner and the 0's aggregating towards the bottom right hand corner.

Referring to FIG. 4, this shows a spiral coder in which the flip flops 42 are arranged in a spiral with the sequence running from the innermost to the outermost, although this sequence could be reversed. Again the input means which effectively determine the order of the sequence is not shown. In the arrangement of FIG. 4 where the flip flop at the centre of the spiral is at the beginning or 1 end, in operation the 1's in the serial input stream will congregate at the centre of the spiral with the 0's at the outside, although this configuration could be reversed.

Referring now to FIG. 5, the weightless thermocoder of this invention can also be used to construct a sum-and-threshold device. For ease of explanation, a simple example is shown of a first stage or layer 44 which comprises a linear array of four flip flops 42 which in this example convert an incoming stream of serial weightless data representing a sum into a rolling thermometer code and a second stage or layer 46 comprising a similar linear array of four flip flops 42 acting as a weightless thermocoder to convert an incoming serial stream of weightless data into a rolling threshold. The outputs from the first and second stages 44,46 pass to a Hamming value comparator stage 48 which determines the Hamming value relationship between the sum thermocode and the threshold thermocode and, in this instance, provides an output at 50 according to whether the Hamming value of the sum is less than, greater than, or equal to the Hamming value of the threshold.

Naturally this principle can be employed with more complex two- and higher-dimensional arrays for example the two-dimensional rectangular array of FIG. 3 or the spiral array of FIG. 4.

In the arrangement of FIG. 5, the Hamming value comparator can take many forms, a typical example being that shown in FIG. 6 which is a Hamming value comparator disclosed in our earlier published International Patent Application WO99/32961. This shows an arrangement for comparing the Hamming values of two weightless binary strings A1 . . . A8 and B1 . . . B8. The arrangement comprises first and second identical arrays of AND gates, OR gates and inverters connected as shown in the Figure to provide an output indicating whether the Hamming value of the weightless binary string A1 . . . A8 is less than, greater than or equal to the Hamming value of the weightless binary string B1 . . . B8.

Referring now to FIG. 7 there is shown a two-dimensional array of flip flops 42 in which the lowermost row 50 of flip flops operates as a thermocoder in a similar fashion to that described in FIG. 2 (the input circuitry is omitted for clarity). However in this arrangement at the end of each cycle the current thermocode result in the lowermost row 50 is shifted upwards, with the rows above also being shifted up one row so as to give a history made up of thermocode results from the previous cycles.

This array is particularly useful for where digital filtering or template matching is required because the successive thermocode results can be operated on. For example, in a digital filter, the bits held by each column of flip flops could be supplied to a sum-and-threshold device to provide a generic template. Again the principle of operation of this arrangement, where the thermocode generator comprises a linear array of four flip flops and associated input circuitry, may be developed and expanded to arrangements where the thermocode generator is for example a two-dimensional aggregate coder as in FIG. 3, or the spiral coder in FIG. 4, and many other schemes.

It should be noted that the techniques disclosed herein are technology independent; they may be implemented for example in optical systems, or by incorporation into a processor architecture, or in electromechanical systems.

1. Apparatus for converting a serial input stream of weightless binary digits into a thermometer code, which comprises:
at least one sequence of bit stores each capable of storing a binary digit, said sequence having a first end and a second end,
input means for receiving said input stream of weightless binary digits and for operating bitwise in use to control the distribution of bits in said bit stores, such that an operation corresponding to or equivalent to the following is performed:
(i) in response to a set bit (1) a bit is set in the bit store at a given end of said sequence and any other set bits in said bit stores are moved incrementally by one bit store towards the other end of the sequence, and
(ii) in response to an unset bit (0) a bit is unset in the bit store at the other end of said sequence and any other unset bits in said bit stores are moved incrementally towards said given end,
whereby the contents of said bit stores represent a thermometer code tuple corresponding to said serial input stream.

2. Apparatus according to claim 1, wherein each of said bit stores comprises a flip flop.

3. Apparatus according to claim 2, wherein each of said flip flops is a D-type flip flop.

4. Apparatus according to claim 1, wherein said input means comprises a network of logic modules associated with respective ones of said bit stores, with each logic module receiving the current bit in said input stream, and a bit stored in at least one of the adjacent bit stores in said sequence.

5. Apparatus according to claim 4, wherein said logic modules comprise a first logic module and a last logic module of different forms, with the intermediate logic modules being of a common form.

6. Apparatus according to claim 1, configured to operate as a planar aggregate coder, wherein the bit stores are arranged generally in a two dimensional rectangular array, with a bit store at one corner of the array defining the first end of said sequence and a bit store in the opposite corner of the array defining the second end of said sequence, with the sequence progressing in serpentine fashion, whereby in use the set bits are grouped in a generally triangular group of said bit stores with the apex of said group being defined by a given one of said end bit stores.

7. Apparatus according to claim 1, configured to act as a spiral aggregate coder wherein the bit stores are arranged generally in a spiral, with an innermost one of said bit stores defining the first end of said sequence and an outermost one of said bit stores defining the other end of said sequence, and the sequence of bit stores progressing generally spirally between the innermost and the outermost.

8. Apparatus according to claim 1, wherein the input means is adapted so that, in operation, the set bits from the input stream generally congregate at the centre of the spiral.

9. Apparatus according to claim 7, wherein the input means is adapted so that, in operation, the unset bits from the input stream generally congregate at the centre of said spiral.

10. Apparatus according to claim 1, wherein the bit stores are arranged in a three-or higher dimensional array with the sequence extending through the array such that, in operation, the set bits aggregate about a preset bit store in said array.

11. Apparatus according to any of claim 1, comprising a two- or higher-dimensional array of bit stores in which a linear selection of bit stores defines said sequence, with the apparatus further including means for shifting the bits from said linear selection of bit stores to another linear selection of bit stores.

12. Apparatus according to claim 11, wherein bits from said linear selection of bit stores are incremented in turn to a succession of linear selections of bit stores.

13. Apparatus according to claim 11, wherein the array of bit stores is two dimensional with a row (or column) of bit stores comprising said linear selection and clock means to clock the values in said bit stores through the `remaining rows (or columns) of the array.

14. A digital filter comprising apparatus according to claim 13, and means for operating on the values in the bit stores to obtain a filtered output.

15. A Hamming value comparator device for receiving a first stream of weightless binary values and a second stream of weightless binary values and for determining a Hamming value relationship between said first and second values, comprises respective first and second thermometer coder each comprising at least one sequence of bit stores and each comprising input means for receiving the associated first or second stream of weightless binary values and for operating bitwise in use to control the distribution of bits in the associated thermometer coder such that an an operation corresponding to or equivalent to the following is performed:
(i) in response to a set bit (1) a bit is set in the bit store at a given end of said sequence and any other set bits in said bit stores are moved incrementally by one bit store towards the other end of the sequence, and
(ii) in response to an unset bit (0) a bit is unset in the bit store at the other end of said sequence and any other unset bits in said bit stores are moved incrementally towards said given end,
whereby the contents of said bit stores represent a thermometer code tuple corresponding to said serial input stream,
and comparison means for comparing the two thermometer codes to determine a Hamming value relationship.

16. Apparatus according to claim 1, wherein each of said bit stores is defined by a shift register.

17. A method of converting a serial stream of weightless data into thermometer code comprises providing a sequence of bit stores and performing in use an operation corresponding to or equal to one in which:
(i) in response to a set bit (1), a set bit is introduced into the bit store at one end of the sequence and the existing bits in the store are each moved on bit store towards the other of the sequence, and
(ii) in response to an unset bit (0), an unset bit is introduced into the bit store at the other end of the sequence and the existing bits are moved one bit store towards said one end of the sequence.
